(19) United States
(12) Patent Application Publication
(10) Pub. No.: US 2024/0030287 A1
(43) Pub. Date: Jan. 25, 2024

(54) SEMICONDUCTOR DEVICES

(71) Applicant: SAMSUNG ELECTRONICS CO., LTD., Suwon-si (KR)

(72) Inventors: Choeun LEE, Suwon-si (KR); Kyungho KIM, Suwon-si (KR); Kanghun MOON, Suwon-si (KR); Kihwan KIM, Suwon-si (KR); Yonguk JEON, Suwon-si (KR)

(21) Appl. No.: 18/340,440

(22) Filed: Jun. 23, 2023

(30) Foreign Application Priority Data
Jul. 25, 2022 (KR) 10-2022-0091946

(51) Int. Cl. H01L 29/08; H01L 29/06; H01L 29/161; H01L 29/423; H01L 29/417; H01L 29/775; H01L 21/02; H01L 29/66

(52) U.S. Cl. CPC H01L 29/0847; H01L 29/0673; H01L 29/161; H01L 29/42392; H01L 29/41733; H01L 29/775; H01L 21/02532; H01L 29/66545; H01L 29/66553; H01L 29/66439

(57) ABSTRACT

A semiconductor device includes a plurality of channel layers on an active region on a substrate, a gate structure surrounding each of the plurality of channel layers, and a source/drain region contacting the plurality of channel layers. The source/drain region comprises a first epitaxial layer including first layers, disposed on side surfaces of the plurality of channel layers, and a second layer, disposed at a lower end of the source/drain region on the active region, and having first impurities, a second epitaxial layer on the active region, filling a space between the first layers and the second layer, having second impurities, different from the first impurities, and having a recessed upper surface, and a third epitaxial layer on the second epitaxial layer. At least a portion of the third epitaxial layer may not include the first impurities and the second impurities.

### CROSS-REFERENCE TO RELATED APPLICATION(S)

This application claims priority under 35 U.S.C. § 119 to Korean Patent Application No. 10-2022-0091946 filed on Jul. 25, 2022 in the Korean Intellectual Property Office, the subject matter of which is hereby incorporated by reference in its entirety.

### BACKGROUND

The inventive concept relates to semiconductor devices.

With demand for semiconductor devices supporting high performance, high speeds, and/or multiple functions increasing, degrees of integration of semiconductor devices have increased. In manufacturing semiconductor devices having fine patterns to meet the need for high integration in semiconductor devices, it is useful to form patterns with fine widths and fine spaces therebetween. Also, efforts to develop semiconductor devices including a fin field-effect transistor (FinFET) having a channel having a three-dimensional structure have been made to help overcome limitations in device characteristics of planar metal oxide semiconductor field-effect transistors (MOSFETs).

### SUMMARY

One or more example embodiments provide a semiconductor device having improved electrical characteristics.

According to an example embodiment, a semiconductor device may include: an active region extending on a substrate in a first direction that may be parallel to an upper surface of the substrate; a plurality of channel layers on the active region and may be spaced apart from each other in a vertical direction that may be perpendicular to the upper surface of the substrate; a gate structure intersecting the active region and the plurality of channel layers and extending on the substrate in a second direction that may be parallel to the upper surface of the substrate, and surrounding each of the plurality of channel layers; and a source/drain region that may be adjacent to the gate structure on the active region and may contact the plurality of channel layers. The source/drain region may include: a first epitaxial layer including first layers that may be on side surfaces of the plurality of channel layers, respectively, and a second layer that may be at a lower end of the source/drain region on the active region wherein the first epitaxial layer may include first impurities; a second epitaxial layer filling a space between the first layers and the second layer, wherein the second epitaxial layer may include second impurities, which may be different from the first impurities, and may include a recessed upper surface; and a third epitaxial layer on the second epitaxial layer. A portion of the third epitaxial layer may not include the first impurities and the second impurities.

According to an example embodiment, a semiconductor device may include: an active region extending on a substrate in a first direction that may be parallel to an upper surface of the substrate; a plurality of channel layers on the active region and may be spaced apart from each other in a vertical direction that may be perpendicular to the upper surface of the substrate; a gate structure intersecting the active region and the plurality of channel layers and extending on the substrate in a second direction that may be parallel to the upper surface of the substrate, and surrounding each of the plurality of channel layers; and a source/drain region that may be adjacent to the gate structure on the active region and may contact the plurality of channel layers. The source/drain region may include: a first epitaxial layer including first layers that may be on side surfaces of the plurality of channel layers, respectively, and a second layer that may be at a lower end of the source/drain region on the active region, wherein the second layer may be separated from the first layers; a second epitaxial layer, filling a space between each of the first layers and the second layer, the second epitaxial layer may include a recessed upper surface; a third epitaxial layer on the second epitaxial layer; and a fourth epitaxial layer between a lower portion of the third epitaxial layer and the recessed upper surface of the second epitaxial layer. A portion of the second epitaxial layer may be in contact with the active region, and the third epitaxial layer may be spaced apart from the first epitaxial layer by the fourth epitaxial layer.

According to an example embodiment, a semiconductor device may include: an active region extending on a substrate in a first direction that may be parallel to an upper surface of the substrate; a plurality of channel layers on the active region and may be spaced apart from each other in a vertical direction that may be perpendicular to the upper surface of the substrate; a gate structure intersecting the active region and the plurality of channel layers and extending on the substrate in a second direction that may be parallel to the upper surface of the substrate, and surrounding each of the plurality of channel layers; and a source/drain region that may be adjacent to the gate structure on the active region and may contact the plurality of channel layers. The source/drain region may include: a first epitaxial layer including first layers on side surfaces of the plurality of channel layers, respectively, and a second layer at a low end of the source/drain region on the active region; a second epitaxial layer, filling a space between the first layers and the second layer, and having a recessed upper surface; a third epitaxial layer on the second epitaxial layer; and a fourth epitaxial layer between the second epitaxial layer and the third epitaxial layer, each of the first epitaxial layer, the second epitaxial layer, and the third epitaxial layer may include a silicon epitaxial layer. The fourth epitaxial layer may include a silicon-germanium layer, and the fourth epitaxial layer has a thickness in a range of about 1 angstrom (Å) to about 2 nanometers (nm).

### BRIEF DESCRIPTION OF DRAWINGS

The above and other aspects, features, and advantages of the present disclosure will be more clearly understood from the following detailed description, taken in conjunction with the accompanying drawings.

FIG. 1 is a plan view of a semiconductor device according to example embodiments.

FIG. 2A illustrates cross-sectional views of a semiconductor device according to example embodiments.

FIG. 2B is a partially enlarged view of a portion of a semiconductor device according to example embodiments and illustrates a distribution of concentration of germanium (Ge) in a source/drain region.

FIG. 3 illustrates cross-sectional views of a semiconductor device according to example embodiments.

FIG. 4A illustrates cross-sectional views of a semiconductor device according to example embodiments.

FIG. 4B is a partially enlarged view of a portion of a semiconductor device according to example embodiments and illustrates a distribution of concentration of germanium (Ge) in a source/drain region.

FIG. 5 illustrates cross-sectional views of a semiconductor device according to example embodiments.

FIGS. 6A to 6K are process cross-sectional views illustrating a method of fabricating a semiconductor device according to example embodiments.

### DETAILED DESCRIPTION

Hereinafter, example embodiments will be described with reference to the accompanying drawings.

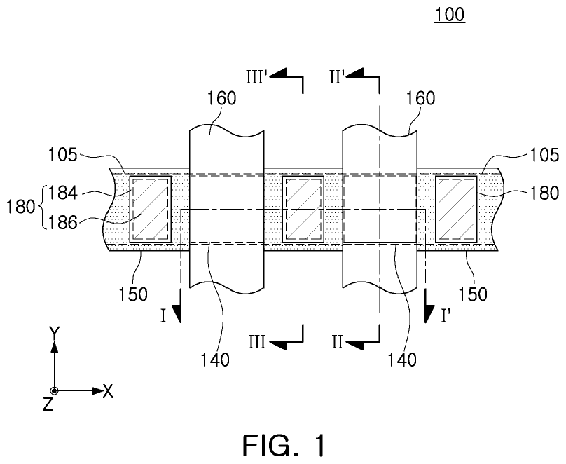

FIG. 1 is a plan view of a semiconductor device according to example embodiments.

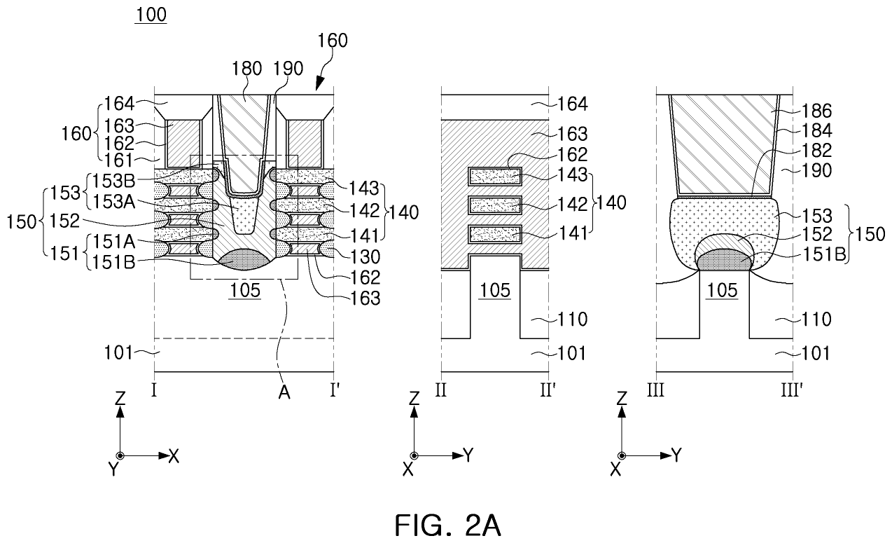

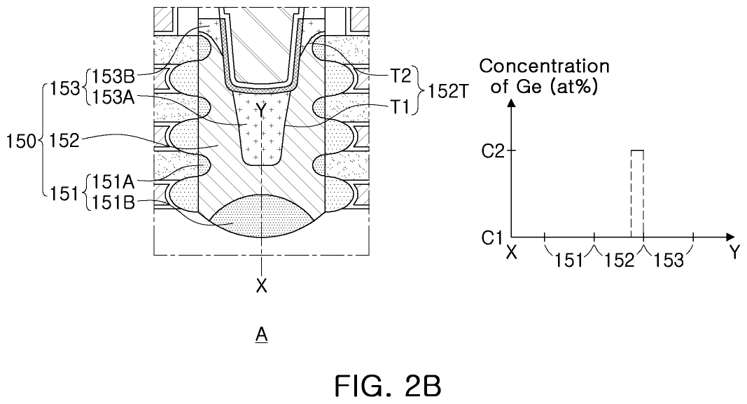

FIG. 2A illustrates cross-sectional views of a semiconductor device according to example embodiments. FIG. 2A illustrates cross-sections, respectively taken along lines I-I′, II-II′, and III-III′ of FIG. 1.

FIG. 2B is a partially enlarged view of a portion of a semiconductor device according to example embodiments and illustrates a distribution of concentration of germanium (Ge) in a source/drain region.

For ease of description, only main components of the semiconductor device are illustrated in FIGS. 1 to 2B.

Referring to FIGS. 1 to 2B, a semiconductor device 100 may include a substrate 101, an active region 105 on the substrate 101, a channel structure 140 including a plurality of channel layers 141, 142, and 143, vertically spaced apart from each other on the active region 105, a source/drain region 150 contacting the plurality of channel layers 141, 142, and 143, internal spacer layers 130 that are on a side surface of the source drain region adjacent to a gate structure (160) in a first direction and are respectively on lower surfaces of the plurality of channel layers 141, 142, and 142, a gate structure 160 extending to intersect the active region 105, and a contact plug 180 connected to source/drain region 150. The semiconductor device 100 may further include isolation layers 110 and an interlayer insulating layer 190. The gate structure 160 may include spacer layers 161, a gate dielectric layer 162, a gate electrode layer 163, and a gate capping layer 164.

In the semiconductor device 100, the active region 105 may have a fin structure, and the gate electrode layer 163 may be disposed between the active region 105 and the channel structure 140, between the plurality of channel layers 141, 142, and 143 of the channel structures 140, and on the channel structure 140. Accordingly, the semiconductor device 100 may include a gate-all-around type field-effect transistor formed by the channel structure 140, the source/drain regions 150, and the gate structure 160, for example, a multi-bridge channel FET (MBCFET™). The transistor may include, for example, NMOS transistors.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The isolation layer 110 may define an active region 105 in the substrate 101. The isolation layer 110 may be formed by, for example, a shallow trench isolation (STI) process. In example embodiments, the isolation layer 110 may further include a region having a step and extending downwardly of the substrate 101. The isolation layer 110 may partially expose an upper portion of the active region 105. In example embodiments, the isolation layer 110 may have a curved upper surface having a level increased in a direction toward the active region 105. The isolation layer 110 may be formed of an insulating material. For example, the isolation layer 110 may be formed of an oxide, a nitride, or a combination thereof.

The active region 105 may be defined by the isolation layers 110 in the substrate 101, and may be disposed to extend in a first direction, for example, the X-direction. The active region 105 may have a structure protruding from the substrate 101. An upper end of the active region 105 may be disposed to protrude from an upper surface of the isolation layers 110 by a predetermined height. The active region 105 may be provided as a portion of the substrate 101, or may include an epitaxial layer grown from the substrate 101. A portion of the active region 105 on the substrate 101 may be recessed on opposite sides adjacent to the gate structure 160, and the source/drain regions 150 may be disposed on the recessed active region 105. The active region 105 may include impurities or doping regions including impurities.

The channel structure 140 may include two or more channel layers, for example, the first to third channel layers 141, 142, and 143, disposed on the active region 105 to be spaced apart from each other in a direction, perpendicular to an upper surface of the active region 105, for example, in a Z-direction. The plurality of channel layers 141, 142, and 143 may include a first channel layer 141 as a lowermost channel layer, a second channel layer 142 as a channel layer directly above the first channel layer 141, and a third channel layer 143 as an uppermost channel layer. The first to third channel layers 141, 142, and 143 may be connected to the source/drain region 150 and may be spaced apart from an upper surface of the active region 105. The first to third channel layers 141, 142, and 143 may have a width the same as or similar to a width of the active region 105 in a Y-direction, and may a width the same as or similar to a width of the gate structure 160 in the X-direction. In example embodiments, the first to third channel layers 141, 142, and 143 may have reduced widths such that side surfaces thereof are disposed below the gate structure 160 in the X-direction. A portion of the widths of the plurality of channel layers 141, 142, and 143 in a vertical direction may be decreased in a direction toward the source/drain region 150. Accordingly, a contact area between the source/drain region 150 and the plurality of channel layers 141, 142, and 143 may be reduced.

The first to third channel layers 141, 142, and 143 may be formed of a semiconductor material and may include, for example, silicon (Si), silicon-germanium (SiGe), or germanium (Ge). The first to third channel layers 141, 142, and 143 may be formed of, for example, the same material as the substrate 101. The plurality of channel layers 141, 142, and 143 may be vertically spaced apart from each other on the active region 105. The number and shape of the plurality of channel layers 141, 142, and 143, constituting a single channel structure 140, may vary according to example embodiments.

The source/drain region 150 may be disposed on the active region 105 that is adjacent to opposite sides of the channel structure 140. The source/drain region 150 may be provided as a source region or a drain region of a transistor. The source/drain region 150 may be disposed by recessing a portion of an upper portion of the active region 105, but presence or absence of the recess and a depth of the recess may vary according to example embodiments. The source/drain region 150 may include a first epitaxial layer 151 disposed on a side surface of each of the first to third channel layers 141, 142, and 143 of the channel structure 140 and at a lower end of the source/drain region 150 on the active region 105, a second epitaxial layer 152 filling a space between the first epitaxial layers 151, and a third epitaxial layer 153 disposed on the second epitaxial layer 152. The source/drain region 150 may include a plurality of epitaxial layers, but example embodiments are not limited thereto. The source/drain region 150 may be a semiconductor layer including silicon (Si) and/or germanium (Ge). The source/drain regions 150 may include impurities of different types and/or concentrations. For example, the source/drain region 150 may include N-type doped silicon (Si) and/or P-type doped silicon-germanium (SiGe). In example embodiments, the source/drain region 150 may include a plurality of regions including elements and/or doping elements having different concentrations. A cross-section of the source/drain region 150 in the Y-direction may have a circular, elliptical, pentagonal, hexagonal, or similar shape. In example embodiments, the source/drain region 150 may have various shapes, for example, one of a polygonal shape, a circular shape, or a rectangular shape.

The first epitaxial layer 151 may include first layers 151A, disposed on side surfaces of the first to third channel layers 141, 142, and 143, and a second layer 15B disposed on an upper surface of the active region 105. The first layers 151A may be disposed on opposite side surfaces of the channel structure 140 in the X-direction. As described above, the first layers 151A including (doped with) arsenic (As) may be disposed on the opposite side surfaces of the channel structure 140 to effectively suppress a short-channel effect caused by diffusion of impurities in the second epitaxial layer 152 including (doped with) phosphorus (P). The first layers 151A may be disposed to be separated from each other between the first to third channel layers 141, 142, and 143 disposed vertically in the Z-direction. The first layers 151A may also be disposed to be spaced apart from the second layer 151B. In addition, the first layers 151A may be disposed to protrude toward the second epitaxial layer 152 from a side surface, a coplanar surface comprising the internal spacer layers 130 and the first to third channel layers 141, 142, and 143. Accordingly, the second epitaxial layer 152 may be interposed between the first layers 151A spaced apart from each other in the Z-direction. Also, the second epitaxial layer 152 may be interposed between the first layers 151A spaced apart from each other in a single source/drain region 150 in the X-direction. Each of the first layers 151A may be surrounded by the second epitaxial layer 152 and a respective one of the plurality of channel layers 141, 142, and 143.

A lower end of the second layer 151B may be disposed on a portion of the upper surface of the active region. For example, the second layer 151B may be disposed in a central region of the active region 105 in the X-direction. The second layer 151B may have a maximum thickness, greater than a thickness of each of the first layers 151A. The second layer 151B may have a shape in which a width of an upper portion is narrower than a width of a lower portion, and may have an upwardly convex shape. An upper end of the second layer 151B may be disposed on a level, higher than a level of a lowermost surface of the gate structure 160. A lower surface of the source/drain region 150 may have various shapes, such as a shape having different degrees of convexity or a planar shape, according to example embodiments. Accordingly, a shape of the second layer 151B may vary according to example embodiments. The first layers 151A and the second layer 151B may be spaced apart from each other.

The first epitaxial layer 151 may be a layer grown epitaxially from the first to third channel layers 141, 142, and 143 and the active region 105. The first epitaxial layer 151 may be a silicon (Si) epitaxial layer. For example, the first epitaxial layer 151 may include N-type impurities such as arsenic (As). The first epitaxial layer 151 may be, for example, a silicon (Si) layer including (doped with) arsenic (As). In some embodiments, the first epitaxial layer 151 may not include germanium (Ge).

The second epitaxial layer 152 may be disposed to completely fill a region between adjacent channel structures 140 and to surround a surface with which the channel structure 140 or the active region 105 is not in contact. The second epitaxial layer 152 may fill a space between the first layers 151A of the first epitaxial layer 151, vertically spaced apart from each other, and may cover (be disposed on) the second layer 151B of the first epitaxial layer 151. The second epitaxial layer 152 may have a recessed upper surface 152T. The second epitaxial layer 152 may be in contact with side surfaces of the internal spacer layers 130 and may be interposed between the first epitaxial layers 151. A portion of the second epitaxial layer 152 may be in contact with the active region 105.

The second epitaxial layer 152 may be a silicon (Si) epitaxial layer. The second epitaxial layer 152 may have a composition, different from a composition of the first epitaxial layer 151. For example, the second epitaxial layer 152 may be a region including impurities at a concentration, higher than a concentration of impurities included in the first epitaxial layer 151. The second epitaxial layer 152 may be a layer grown epitaxially from the first epitaxial layer 151. The impurities may be the same as or different from those included in the first epitaxial layer 151. For example, the second epitaxial layer 152 may be a silicon phosphide (SiP) layer including phosphorus (P). In example embodiments, the first epitaxial layer 151 may be a silicon (Si) epitaxial layer including (doped with) arsenic (As), and the second epitaxial layer 152 may be a silicon (Si) layer including (doped with) phosphorus (P). For example, the first epitaxial layer 151 and the second epitaxial layer 152 may include different impurities.

A shape, a disposition, or the like, of the second epitaxial layer 152 may be determined depending on reflow conditions, or the like, in a process of forming the source/drain region 150. For example, when a temperature of a reflow process is set to be relatively high after the formation of the second epitaxial layer 152, the reflow degree of the second epitaxial layer 152 may be increased and the second epitaxial layer 152 may be disposed on a level, lower than a level of an uppermost portion of the first layers 151A.

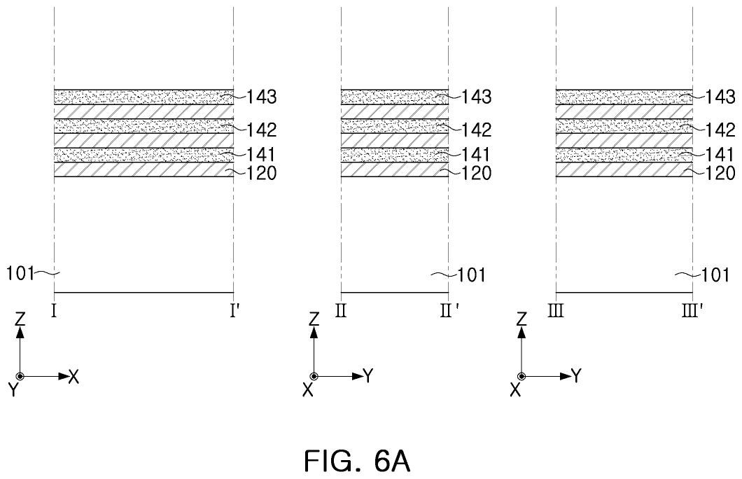

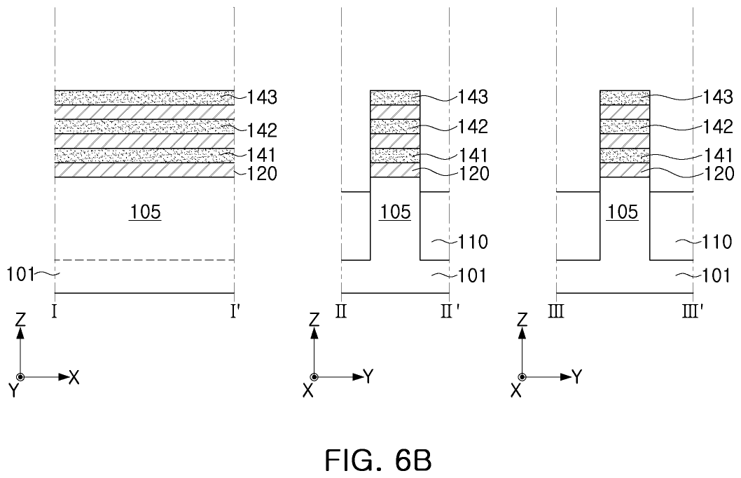

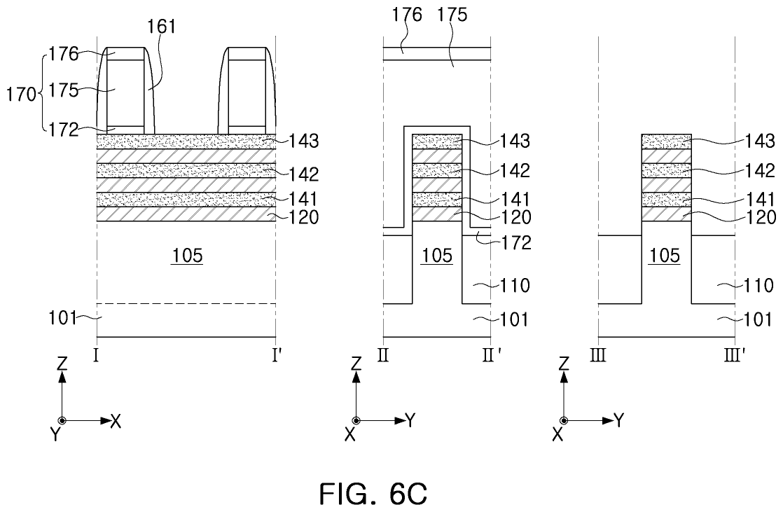

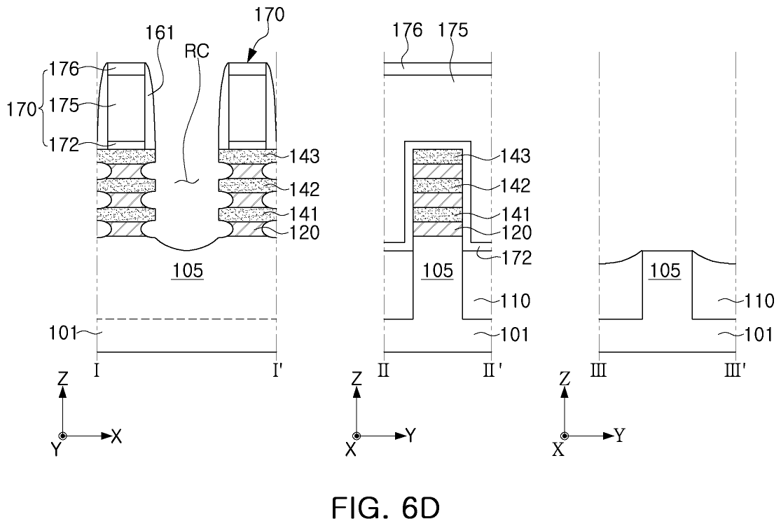

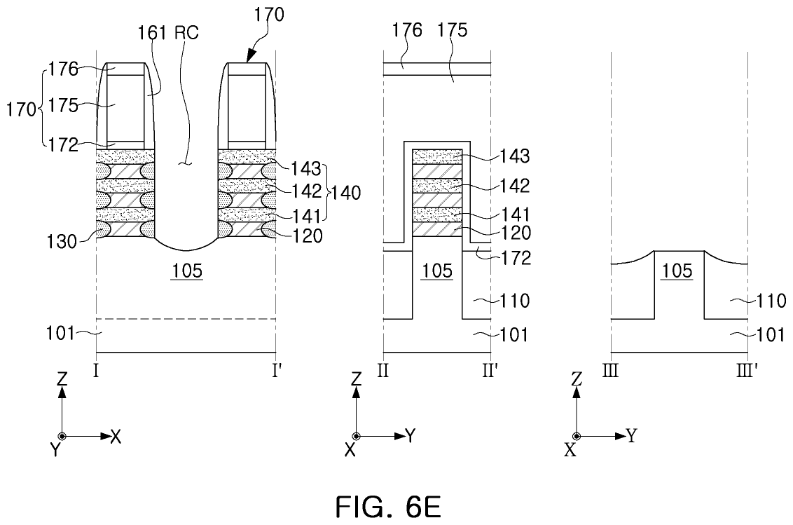

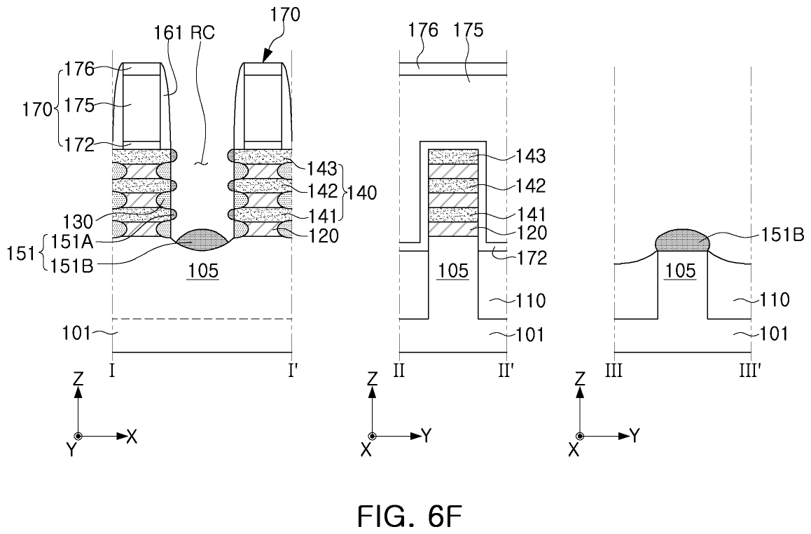

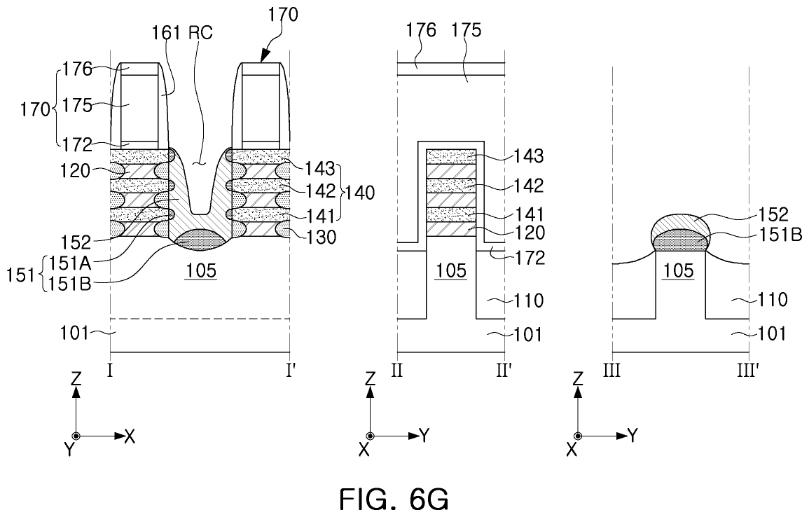

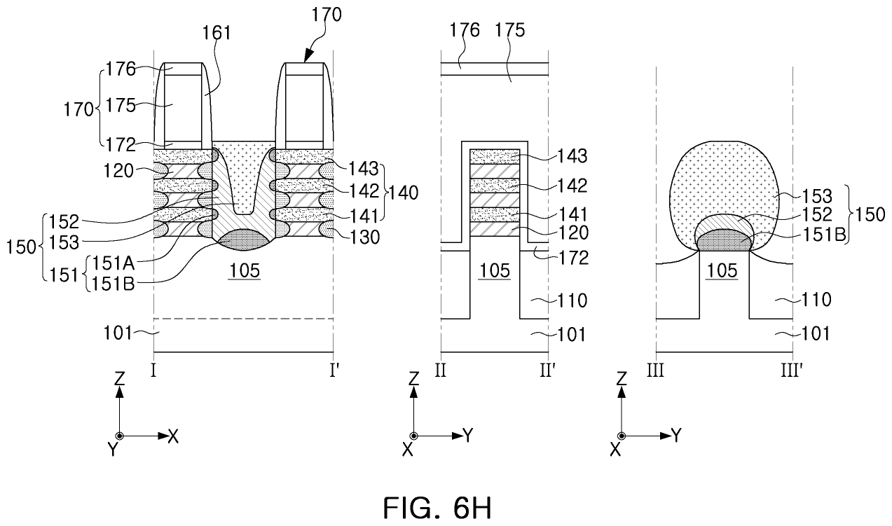

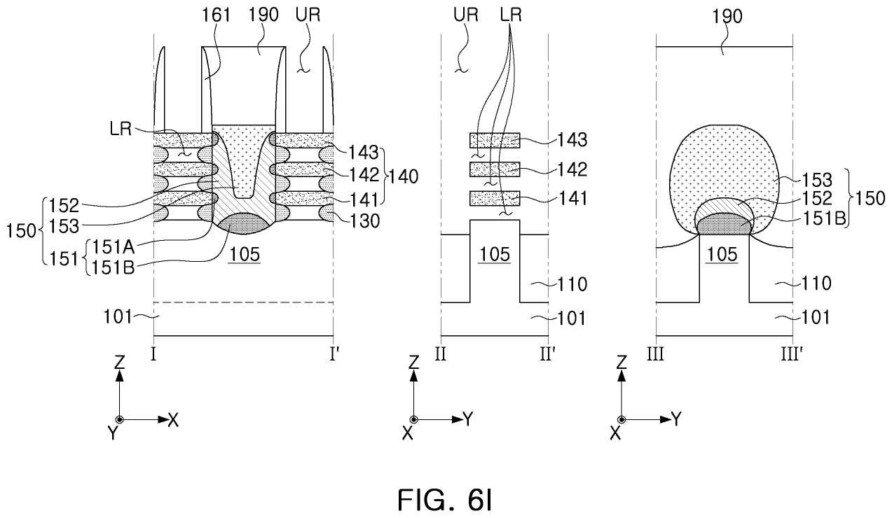

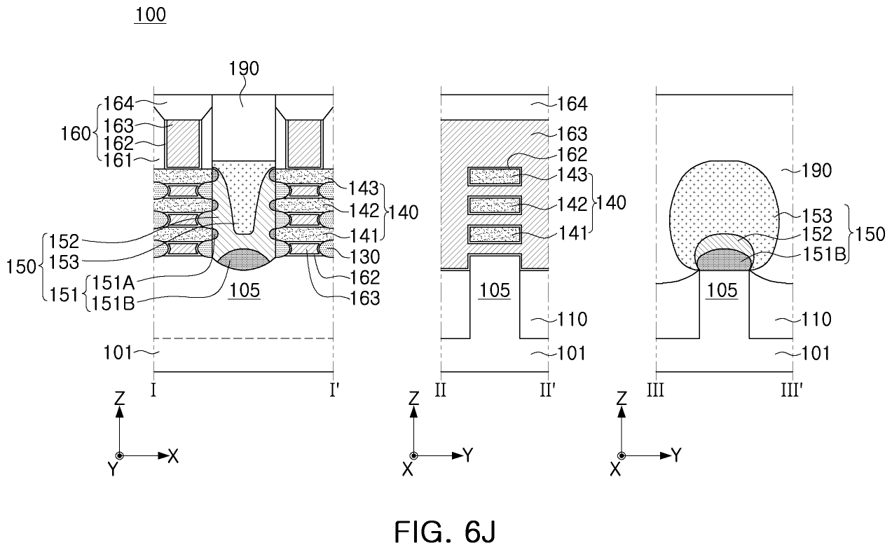

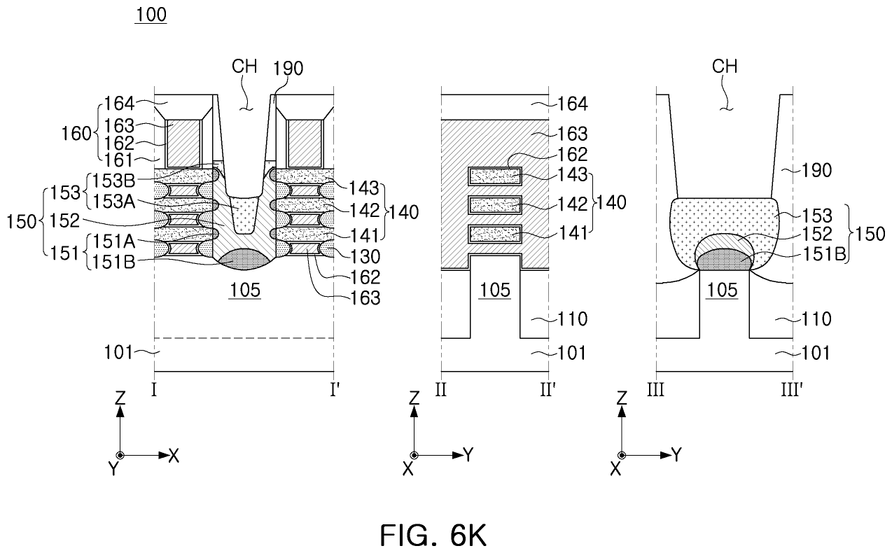

As illustrated in FIG. 2B, the second epitaxial layer 152 may include germanium (Ge). The first epitaxial layer 151 and the third epitaxial layer 153 may substantially not include germanium (Ge) at a first concentration C1. For example, the first concentration C1 is about 0 atomic percentage (at %). The second epitaxial layer 152 may include germanium (Ge) at a second concentration C2 in a boundary portion of the third epitaxial layer 153 due to a process to be described in FIG. 6. For example, the second epitaxial layer 152 may include germanium (Ge) within a range of greater than about 0 at % to about 10 at %, in detail, within a range of about 3 at % to about 7 at %. In example embodiments, the second epitaxial layer 152 may include about 5 at % of germanium (Ge).

The third epitaxial layer 153 may be a silicon (Si) epitaxial layer. The third epitaxial layer 153 may be disposed on the second epitaxial layer 152. The third epitaxial layer 153 may include a first portion 153A, disposed below the contact plug 180 to be described later, and a second portion 153B disposed on a side surface of the contact plug 180. The first portion 153A may be spaced apart from the second portion 153B by the contact plug 180. A portion of the third epitaxial layer 153 may not include impurities. For example, the third epitaxial layer 153 may include undoped silicon (Si), unlike the first epitaxial layer 151 and the second epitaxial layer 152. The third epitaxial layer 153 may cover (be disposed on) the first epitaxial layer 151 and the second epitaxial layer 152. The third epitaxial layer 153 may be in contact with a portion of the first epitaxial layer 151. For example, when the reflow degree of the second epitaxial layer 152 is increased, the third epitaxial layer 153 may be in contact with an uppermost portion of the first layers 151A. An uppermost portion of the third epitaxial layer 153 may be disposed on a level, higher than a level of an upper surface of the uppermost channel layer 143, among the plurality of channel layers 141, 142, and 143. A lowermost portion of the third epitaxial layer 153 may be disposed on a level, lower level than a level of a lower surface of the second channel layer 142.

The internal spacer layers 130 may be disposed to be parallel to the gate electrode layer 163 between the channel structures 140. The gate electrode layer 163 may be spaced apart from the source/drain region 150 below the third channel layer 143 by the internal spacer layers 130 to be electrically separated from each other. The internal spacer layers 130 may have a shape in which a side surface, facing the gate electrode layer 163, is rounded to be convex inwardly of the gate electrode layer 163, but example embodiments are not limited thereto. The internal spacer layers 130 may be formed of an oxide, a nitride, or an oxynitride. In particular, the internal spacer layers 130 may include a low-K dielectric layer.

The internal spacer layers 130 may be formed of the same material as the spacer layers 161, but example embodiments are not limited thereto. For example, the internal spacer layers 130 may include SiN, SiCN, SiOCN, SiBCN, or SiBN. The internal spacer layers 130 may also be applied to other embodiments.

The gate structure 160 may be disposed to extend in one direction, for example, in the Y-direction, while intersecting the active region 105 and the channel structures 140 on the active region 105 and the channel structures 140. Channel regions of transistors may be formed in the active region 105 and the channel structures 140 intersecting the gate structure 160. The gate structure 160 may include a gate electrode layer 163, a gate dielectric layer 162 between the gate electrode layer 163 and the plurality of channel layers 141, 142, and 143, and spacer layers 161 on side surfaces of the gate electrode layer 163, and a gate capping layer 164 on an upper surface of the gate electrode layer 163. The gate structure 160 may surround upper and lower surfaces of the plurality of channel layers 141, 142, and 143, and side surfaces thereof in the first direction X. A lowermost portion of the source/drain region 150 may be disposed on a level, lower than a level of a lowermost portion of the gate structure 160.

The gate dielectric layer 162 may be disposed between the active region 105 and the gate electrode layer 163 and between the channel structure 140 and the gate electrode layer 163, and may be disposed to cover a portion of surfaces of the gate electrode layer 163. For example, the gate dielectric layer 162 may be disposed to surround all surfaces, except for an uppermost surface of the gate electrode layer 163. The gate dielectric layer 162 may extend between the gate electrode layer 163 and the spacer layers 161, but example embodiments are not limited thereto. The gate dielectric layer 162 may include an oxide, a nitride, or a high-K dielectric material. The high-K dielectric material may refer to a dielectric material having a dielectric constant, higher than a dielectric constant a silicon oxide (SiO₂). The high-K dielectric material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate electrode layer 163 may be disposed on the active region 105 to fill spaces between the plurality of channel layers 141, 142, and 143 and to extend upwardly of the channel structure 140. The gate electrode layer 163 may be spaced apart from the plurality of channel layers 141, 142, and 143 by the gate dielectric layer 162. The gate electrode layer 163 may include a conductive material. For example, the gate electrode layer 163 may include a metal nitride such as a titanium nitride (TiN), a tantalum nitride (TaN), or a tungsten nitride (WN), and/or a metal material such as aluminum (Al), tungsten (W), or molybdenum (Mo), or a semiconductor material such as doped polysilicon.

The gate electrode layer 163 may have two or more layers. The spacer layers 161 may be disposed on opposite side surfaces of the gate electrode layer 163. The spacer layers 161 may insulate the source/drain region 150 from the gate electrode layer 163. The spacer layers 161 may have a multilayer structure according to example embodiments. The spacer layers 161 may include an oxide, a nitride, an oxynitride, or a low-K dielectric material.

The gate capping layer 164 may be disposed on the gate electrode layer 163. The gate capping layer 164 may be disposed to extend along an upper surface of the gate electrode layer 163 in a second direction, for example, the Y-direction. Side surfaces of the gate capping layer 164 may be surrounded by spacer layers 161. An upper surface of the gate capping layer 164 may be substantially coplanar with upper surfaces of the spacer layers 161, but example embodiments are not limited thereto. The gate capping layer 164 may be formed of an oxide, a nitride, or an oxynitride, and may include, for example, SiO, SiN, SiCN, SiOC, SiON, or SiOCN.

The interlayer insulating layer 190 may be disposed to cover the source/drain region 150, the gate structure 160, and the isolation layer 110. The interlayer insulating layer 190 may include, for example, an oxide, a nitride, an oxynitride, or a low-K dielectric material.

The contact plug 180 may penetrate through a portion of the interlayer insulating layer 190, the second epitaxial layer 152, and/or the third epitaxial layer 153 to be in contact with the source/drain region 150, and may apply an electrical signal to the source/drain region 150. The contact plug 180 may be disposed on the source/drain region 150, and may be disposed to have a larger length in the Y-direction than the source/drain region 150 according to example embodiments. The contact plug 180 may have an inclined side surface in which a width of a lower portion is narrower than a width of an upper portion depending on an aspect ratio, but example embodiments are not limited thereto. The contact plug 180 may be disposed to recess the source/drain region 150 to a predetermined depth. The contact plug 180 may include a metal-semiconductor compound layer 182 disposed on a lower end thereof, a barrier layer 184 disposed along a sidewall thereof, and a plug conductive layer 186. The metal-semiconductor compound layer 182 may be, for example, a metal silicide layer. The metal-semiconductor compound layer 182 may be in contact with the second epitaxial layer 152 and/or the third epitaxial layer 153. For example, the metal-semiconductor compound layer 182 may be in contact with the second epitaxial layer 152 and the third epitaxial layer 153. The barrier layer 184 may include, for example, a metal nitride such as a titanium nitride (TiN), a tantalum nitride (TaN), or a tungsten nitride (WN). The plug conductive layer 186 may include, for example, a metal material such as aluminum (Al), tungsten (W), or molybdenum (Mo). In example embodiments, the contact plug 180 may be disposed to penetrate through a portion of the source/drain region 150.

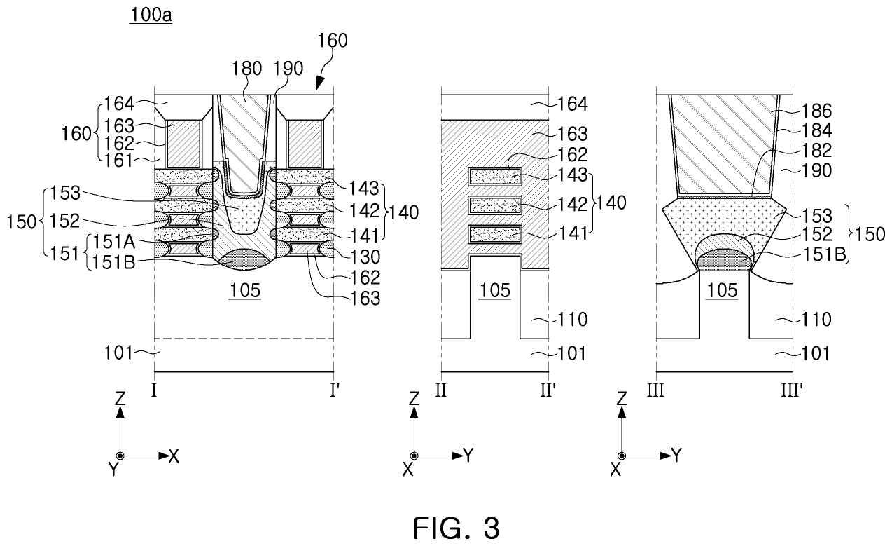

FIG. 3 illustrates cross-sectional views of a semiconductor device 100a according to example embodiments.

In FIGS. 3 to 5, the same reference numerals as those of FIG. 2A denote corresponding components, and redundant descriptions thereof will be omitted.

Unlike the embodiment of FIG. 2A, a metal-semiconductor compound layer 182 may not be in contact with a second epitaxial layer 152, but may be in contact with a third epitaxial layer 153. A cross-section source/drain region 150 in a Y-direction may have a circular, elliptical, pentagonal, hexagonal, or similar shape. In example embodiments, the source/drain region 150 may have various shapes, for example, a pentagonal shape as illustrated in FIG. 3. A transistor may include, for example, PMOS transistors.

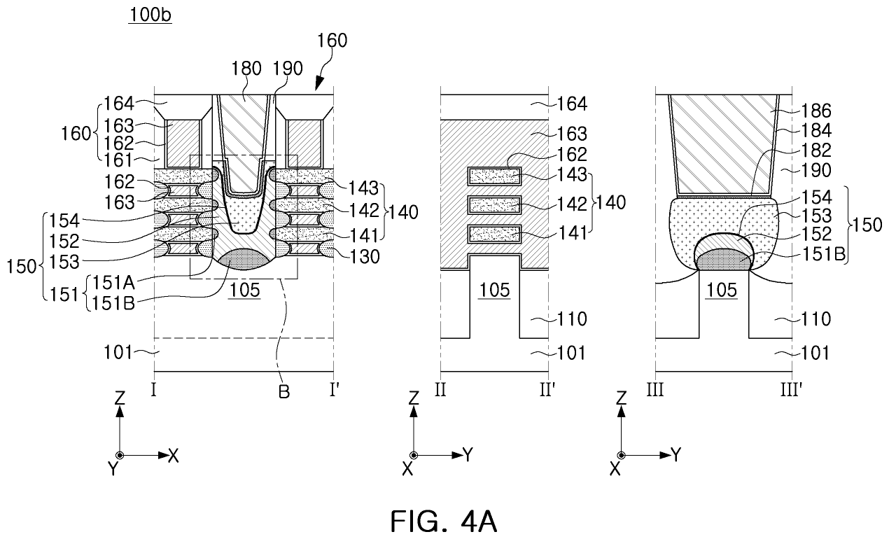

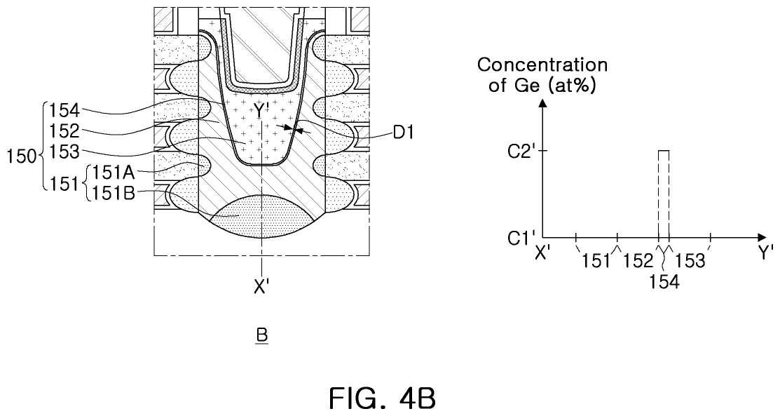

FIG. 4A illustrates cross-sectional views of a semiconductor device 100b according to example embodiments.

FIG. 4B is a partially enlarged view of a portion of the semiconductor device 100b according to example embodiments and illustrates a distribution of concentration of germanium (Ge) in a source/drain region.

Unlike the embodiment of FIG. 2A, the semiconductor device 100b of FIG. 4A may further include a fourth epitaxial layer 154. The fourth epitaxial layer 154 may be disposed between a second epitaxial layer 152 and a third epitaxial layer 153. The fourth epitaxial layer 154 may be disposed below the third epitaxial layer 153 and along a recessed upper surface 152T of the second epitaxial layer 152. The fourth epitaxial layer 154 may be substantially conformal. For example, the fourth epitaxial layer 154 may have a thickness substantially uniform along the lower portion of the third epitaxial layer and the recessed upper surface of the second epitaxial layer. The fourth epitaxial layer 154 may have a thickness in a range of about 1 angstrom (Å) to about 2 nanometers (nm), in detail, in a range of about 1 nm to about 2 nm.

The fourth epitaxial layer may be a silicon-germanium (SiGe) epitaxial layer. As illustrated in FIG. 4B, the first epitaxial layer 151, the second epitaxial layer 152, and the third epitaxial layer 153 may not substantially include germanium (Ge) at a third concentration C1′. For example, the first concentration C1′ is about 0 at %.

The fourth epitaxial layer 154 may include germanium (Ge) at a fourth concentration C2′. For example, the fourth epitaxial layer 154 may include germanium (Ge) within a range of greater than about 5 at % to about 20 at %, in detail, within a range of about 10 at % to about 15 at %.

The contact plug 180 may penetrate through a portion of the interlayer insulating layer 190, the second epitaxial layer 152, the third epitaxial layer 153, and/or the fourth epitaxial layer 154. For example, the metal-semiconductor compound layer 182 may be in contact with the third epitaxial layer 153 as illustrated in FIG. 4B. However, example embodiments are not limited thereto, and the metal-semiconductor compound layer 182 may be in contact with the second epitaxial layer 152, the epitaxial layer 153, and the fourth epitaxial layer 154.

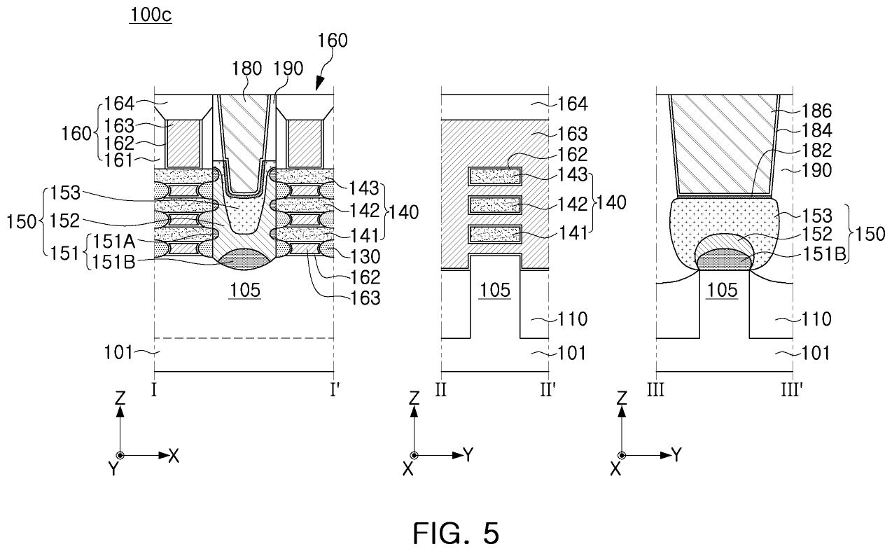

FIG. 5 illustrates cross-sectional views of a semiconductor device 100c according to example embodiments.

Unlike the embodiment of FIG. 2A, a contact plug 180 of the semiconductor device 100c of FIG. 5 may not be in contact with the second epitaxial layer 152 and may be in contact with a third epitaxial layer 153. For example, a metal-semiconductor compound layer 182 may be in contact with the third epitaxial layer 153 including silicon (Si) without impurities (e.g., undoped silicon).

FIGS. 6A to 6K are process cross-sectional views illustrating a method of fabricating a semiconductor device 100 according to example embodiments.

FIGS. 6A to 6K illustrate an example embodiment of a method of fabricating the semiconductor device 100 of FIGS. 1 to 2B, and illustrate cross-sections corresponding to FIG. 2A.

Referring to FIG. 6A, sacrificial layers 120 and a plurality of channel layers 141, 142, and 143 may be alternately stacked on an active region 105.

The sacrificial layers 120 may be replaced with a gate dielectric layer 162 and a gate electrode layer 163 through a subsequent process, as illustrated in FIG. 2A. The sacrificial layers 120 may be formed of a material having etch selectivity with respect to the plurality of channel layers 141, 142, and 143. The plurality of channel layers 141, 142, and 143 may include a material, different from a material of the sacrificial layers 120. In example embodiments, the plurality of channel layers 141, 142, and 142 may include silicon (Si), and the sacrificial layers 120 may include silicon-germanium (SiGe).

The sacrificial layers 120 and the plurality of channel layers 141, 142, and 143 may be formed by performing an epitaxial growth process using the substrate 101 as a seed. Each of the sacrificial layers 120 and the plurality of channel layers 141, 142, and 143 may have a length in a range of about 1 Å to 100 nm. The number of the plurality of channel layers 141, 142, and 143, stacked alternately with the sacrificial layer 120, may vary according to example embodiments.

Referring to FIG. 6B, a stack structure of the sacrificial layers 120 and the plurality of channel layers 141, 142, and 143, and a portion of the substrate 101 may be removed to form active structures.

The active structure may include the sacrificial layers 120 and the plurality of channel layers 141, 142, and 143 stacked alternately with each other, and may further include an active region 105 formed to protrude to an upper surface of a substrate 101 by removing a portion of the substrate 101. The active structures may be formed to have a linear shape extending in one direction, for example, an X-direction, and may be disposed to be spaced apart from each other in a Y-direction.

An insulating material may fill a region in which a portion of the substrate 101 is removed, and may then be recessed such that the active region 105 protrudes, and thus isolation layers 110 may be formed. A level of upper surfaces of the isolation layers 110 may be lower than a level of an upper surface of the active region 105.

Referring to FIG. 6C, sacrificial gate structures 170 and spacer layers 161 may be formed on the active structures.

The sacrificial gate structures 170 may be sacrificial structures formed in a region, in which the gate dielectric layer 162 and the gate electrode layer 163 are disposed on the channel structure 140, through a subsequent process, as illustrated in FIG. 2A. The sacrificial gate structures 170 may include first and second sacrificial gate layers 172 and 175 and a mask pattern layer 176, stacked sequentially. The first and second sacrificial gate layers 172 and 175 may be patterned using a mask pattern layer 176. The first and second sacrificial gate layers 172 and 175 may be an insulating layer and a conductive layer, respectively. For example, the first sacrificial gate layer 172 may include a silicon oxide, and the second sacrificial gate layer 175 may include polysilicon. The mask pattern layer 176 may include a silicon nitride. The sacrificial gate structures 170 may have a linear shape intersecting the active structures and extending in one direction. The sacrificial gate structures 170 may extend in, for example, a Y-direction and may be disposed to be spaced apart from each other in an X-direction.

The spacer layers 161 may be formed on opposite sidewalls of the sacrificial gate structures 170. The spacer layers 161 may be formed by forming a layer having a uniform thickness along upper and side surfaces of the sacrificial gate structures 170 and the active structures and anisotropically etching the layer. The spacer layers 161 may be formed of a low-K dielectric material, and may include, for example, SiO, SiN, SiCN, SiOC, SiON, or SiOCN.

Referring to FIG. 6D, the exposed sacrificial layers 120 and the plurality of channel layers 141, 142, and 143 may be removed to form a recess region RC, and thus channel structures 140 may be formed, between the sacrificial gate structures 170.

The exposed sacrificial layers 120 and the plurality of channel layers 141, 142, and 143 may be removed using the sacrificial gate structures 170 and the spacer layers 161 as masks. The remaining sacrificial layers 120 may be selectively etched with respect to the channel structures 140 by, for example, a wet etching process and removed to a predetermined depth from a side surface thereof in the X-direction to have inwardly concave side surfaces. However, when the remaining sacrificial layers 120 are removed from the side surface thereof in the X-direction, a portion of ends of the channel structures 140 may be removed. Side surface of the remaining plurality of channel layers 141, 142, and 143 in the X-direction may be etched to have outwardly convex side surfaces. However, shapes of the side surfaces of the sacrificial layers 120 and the plurality of channel layers 141, 142, and 143 are not limited to those illustrated in the drawing.

Referring to FIG. 6E, internal spacer layers 130 may be formed in a region in which the sacrificial layers 120 are removed.

The internal spacer layers 130 may be formed in a region in which the sacrificial layers 120 and the plurality of channel layers 141, 142, and 143 are removed. The internal spacer layers 130 may be formed by filling the region, in which the sacrificial layers 120 and the plurality of channel layers 141, 142, and 143 are removed, with an insulating material and then removing the insulating material deposited on an external side of the channel structures 140. The internal spacer layers 130 may be formed of the same material as the spacer layers 161, but example embodiments are not limited thereto. For example, the internal spacer layers 130 may include SiN, SiCN, SiOCN, SiBCN, or SiBN.

Referring to FIG. 6F, a first epitaxial layer 151 for forming a source/drain region 150 in the recess region RC may be formed on opposite sides adjacent to the sacrificial gate structures 170.

The first epitaxial layer 151 may be formed on side surfaces of the first to third channel layers 141, 142, and 143, respectively, by, for example, a selective epitaxial growth (SEG) process, and may also be formed on a bottom surface of the recess region RC in the active region 105. The first epitaxial layer 151 may include impurities by in-situ doping. The first epitaxial layer 151 may be, for example, a silicon arsenide (SiAs) layer. The first layers 151A of the first epitaxial layer 151 may be formed on side surfaces of the first to third channel layers 141, 142, and 143, and the second layer 151B of the first epitaxial layer 151 may be formed on the bottom surface of in the recess region RC (e.g., at a lower end of the source/drain region 150). The first layers 151A may be formed to have outwardly convex surfaces on the side surfaces of the first to third channel layers 141, 142, and 143, but example embodiments are not limited thereto. The second layer 151B may be formed on a surface of the active region 105 to have a surface upwardly convex from the bottom surface of the recess region RC, but example embodiments are not limited thereto. The first epitaxial layer 151 may include first layers 151A and a second layer 151B. An upper end of the second layer 151B may be disposed on a level, higher than a level of a lowermost surfaces of the sacrificial gate structures 170, but example embodiments are not limited thereto because the second layer 151B may be formed by controlling a growth rate and a growth thickness of the first epitaxial layer 151 in the present operation.

Referring to FIG. 6G, a second epitaxial layer 152 may be formed on the first epitaxial layer 151, and a portion of the second epitaxial layer 152 may then be etched. Then, the second epitaxial layer 152 may be reflowed.

The second epitaxial layer 152 may be a silicon phosphide (SiP) layer including phosphorus (P) as a doping element.

Then, a portion of the second epitaxial layer 152 may be etched using germane (GeH₄) and hydrochloric acid (HCl). Therefore, germanium (Ge) may be detected on a surface of the second epitaxial layer 152.

Then, heat may be supplied to the first epitaxial layer 151 and the second epitaxial layer 152, grown in the recess region RC, together with carrier gas. The carrier gas may be, for example, hydrogen (H₂) gas. When heat is supplied to the first epitaxial layer 151 and the second epitaxial layer 152, grown in the recess region RC, together with the carrier gas, atoms of each of the epitaxial layers may be moved in a direction in which total surface energy is reduced, for example, in a vertically downward direction (in a negative Z-direction). Accordingly, a surface of the second epitaxial layer 152 may have a gently curved shape, as illustrated in FIG. 6G.

Referring to FIG. 6H, a third epitaxial layer 153 may be formed on the second epitaxial layer 152.

In example embodiments, a portion of the third epitaxial layer 153 may include silicon (Si) without impurities (e.g., undoped silicon).

Referring to FIG. 6I, an interlayer insulating layer 190 may be formed, and the sacrificial layers 120 and the sacrificial gate structures 170 may be removed.

The interlayer insulating layer 190 may be formed by forming an insulating layer to cover the sacrificial gate structures 170 and the source/drain regions 150 and then performing a planarization process.

The sacrificial layers 120 and the sacrificial gate structures 170 may be selectively removed with respect to the spacer layers 161, the interlayer insulating layer 190, and the plurality of channel layers 141, 142, and 143. Upper gap regions UR may be formed by removing the sacrificial gate structures 170, and then the sacrificial layers 120 exposed through the upper gap regions UR may be removed to form lower gap regions LR. For example, when the sacrificial layers 120 include silicon-germanium (SiGe) and the plurality of channel layers 141, 142, and 143 include silicon (Si), the sacrificial layers 120 may be selectively removed by performing a wet etching process using peracetic acid and/or a solution (NH₄OH:H₂O₂:H₂O=1:1:5), used in a standard clean-1 (SC1) cleaning process, as an etchant. The source/drain region 150 may be protected by the interlayer insulating layer 190 formed on an outermost layer of the source/drain region 150 and the internal spacer layers 130 having a selective etch ratio.

Referring to FIG. 6J, a gate structure 160 may be formed in the upper gap regions UR and the lower gap regions LR.

The gate dielectric layer 162 may be formed to conformally cover internal surfaces of the upper gap regions UR and the lower gap regions LR. The gate electrode layer 163 may be formed to fill the upper gap regions UR and the lower gap regions LR. The gate electrode layer 163 and the spacer layers 161 may be removed from above to a predetermined depth in the upper gap regions UR. A gate capping layer 164 may be formed in a region, in which the gate electrode layer 163 and the spacer layers 161 are removed, in the upper gap regions UR. Accordingly, a gate structure 160 including the gate dielectric layer 162, the gate electrode layer 163, the spacer layers 161, and the gate capping layer 164 may be formed.

Referring to FIG. 6K, contact holes CH may be formed to expose the source/drain region 150. Lower surfaces of the contact holes CH may be recessed into the source/drain region 150.

Returning to FIGS. 1, 2A, and 2B, the contact plug 180 may be formed in the contact holes CH. The contact plug 180 may include a metal-semiconductor compound layer 182 disposed on a lower end thereof, a barrier layer 184 disposed along sidewalls, and a plug conductive layer 186.

In example embodiment, the contact plug 180 may be disposed to penetrate through a portion of the interlayer insulating layer 190 and to be in contact with the source/drain region 150. In this case, the metal-semiconductor compound layer 182 of the contact plug 180 may be in contact with a portion of the source/drain region 150, and a lower end of the metal-semiconductor compound layer 182 may be disposed on a level, lower than a level of upper ends of the plurality of channel layers 141, 142, 143. However, a shape and a disposition of the contact plug 180 are not limited thereto, and may vary according to example embodiments.

As described above, in a source/drain region, deformation of the source/drain region may be significantly reduced through a third epitaxial layer without impurities (e.g., undoped third epitaxial layer). Thus, a semiconductor device having improved electrical characteristics may be provided.

While example embodiments have been shown and described above, it will be apparent to those skilled in the art that modifications and variations could be made without departing from the scope of the present inventive concept as defined by the appended claims.

Herein, a lower side, a lower portion, a lower surface, and the like, are used to refer to a direction toward a lower structure or a substrate in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an intermediate layer as well as a direct connection between two components with or without intervening layers or components. In addition, “electrically separated” conceptually includes a physical separation and a physical connection. It can be understood that when an element is referred to with terms such as “first” and “second”, the element is not limited thereby. They may be used only for a purpose of distinguishing an element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

What is claimed is:

1. A semiconductor device comprising:
an active region extending on a substrate in a first direction that is parallel to an upper surface of the substrate;
a plurality of channel layers on the active region and are spaced apart from each other in a vertical direction that is perpendicular to the upper surface of the substrate;
a gate structure intersecting the active region and the plurality of channel layers and extending on the substrate in a second direction that is parallel to the upper surface of the substrate, and surrounding each of the plurality of channel layers; and
a source/drain region that is adjacent to the gate structure on the active region and contacts the plurality of channel layers,
wherein the source/drain region comprises:
a first epitaxial layer including first layers that are on side surfaces of the plurality of channel layers, respectively, and a second layer that is at a lower end of the source/drain region on the active region, wherein the first epitaxial layer includes first impurities;
a second epitaxial layer filling a space between the first layers and the second layer, wherein the second epitaxial layer includes second impurities, which are different from the first impurities, and includes a recessed upper surface; and
a third epitaxial layer on the second epitaxial layer,
wherein a portion of the third epitaxial layer does not include the first impurities and the second impurities.

2. The semiconductor device of claim 1, wherein
the first layers and the second layer are spaced apart from each other.

3. The semiconductor device of claim 1, further comprising:
internal spacer layers that are on a side surface of the source/drain region adjacent to the gate structure in the first direction and are respectively on lower surfaces of the plurality of channel layers.

4. The semiconductor device of claim 3, wherein
the first layers protrude toward the second epitaxial layer from a side surface comprising the internal spacer layers and the plurality of channel layers.

5. The semiconductor device of claim 3, wherein
each of the first layers is surrounded by the second epitaxial layer and a respective one of the plurality of channel layers.

6. The semiconductor device of claim 1, wherein
the first epitaxial layer includes a first material different from a second material included in the second epitaxial layer.

7. The semiconductor device of claim 1, wherein
the third epitaxial layer is in contact with a portion of the first epitaxial layer.

8. The semiconductor device of claim 1, wherein
an upper end of the second layer is disposed on a level, higher than a level of a lowermost layer of the gate structure.

9. The semiconductor device of claim 1, wherein
an upper end of the third epitaxial layer is disposed on a level, higher than a level of an upper surface of an uppermost channel layer, among the plurality of channel layers.

10. The semiconductor device of claim 1, further comprising:
an interlayer insulating layer on the third epitaxial layer; and
a contact plug penetrating through a portion of the interlayer insulating layer, the third epitaxial layer, and the second epitaxial layer.

11. The semiconductor device of claim 10, wherein
the contact plug is spaced apart from the second epitaxial layer by the third epitaxial layer.

12. The semiconductor device of claim 10, wherein
the contact plug includes a metal-semiconductor compound layer, and
the metal-semiconductor compound layer is in contact with the second epitaxial layer and the third epitaxial layer.

13. The semiconductor device of claim 12, wherein
the third epitaxial layer includes a first portion, disposed below the contact plug, and a second portion on a side surface of the contact plug, and
the first portion is spaced apart from the second portion by the contact plug.

14. A semiconductor device comprising:
an active region extending on a substrate in a first direction that is parallel to an upper surface of the substrate;
a plurality of channel layers on the active region and are spaced apart from each other in a vertical direction that is perpendicular to the upper surface of the substrate;
a gate structure intersecting the active region and the plurality of channel layers and extending on the substrate in a second direction that is parallel to the upper surface of the substrate, and surrounding each of the plurality of channel layers; and
a source/drain region that is adjacent to the gate structure on the active region and contacts the plurality of channel layers,
wherein the source/drain region comprises:
a first epitaxial layer including first layers that are on side surfaces of the plurality of channel layers, respectively, and a second layer that is at a lower end of the source/drain region on the active region, wherein the second layer is separated from the first layers;
a second epitaxial layer, filling a space between each of the first layers and the second layer, the second epitaxial layer includes a recessed upper surface;
a third epitaxial layer on the second epitaxial layer; and
a fourth epitaxial layer between a lower portion of the third epitaxial layer and the recessed upper surface of the second epitaxial layer,
a portion of the second epitaxial layer is in contact with the active region, and
the third epitaxial layer is spaced apart from the first epitaxial layer by the fourth epitaxial layer.

15. The semiconductor device of claim 14, wherein
the fourth epitaxial layer has a thickness substantially uniform along the lower portion of the third epitaxial layer and the recessed upper surface of the second epitaxial layer, and
the thickness is in a range of about 1 angstrom (Å) to about 2 nanometers (nm).

16. The semiconductor device of claim 14, wherein
a portion of the third epitaxial layer does not include impurities, and
the fourth epitaxial layer includes silicon-germanium.

17. The semiconductor device of claim 14, wherein
a thickness of each of the plurality of channel layers in the vertical direction decreases in a direction toward the source/drain region.

18. The semiconductor device of claim 14, wherein
an uppermost portion of the third epitaxial layer is disposed on a level, higher than a level of an uppermost portion of the plurality of channel layers.

19. The semiconductor device of claim 14, wherein
the plurality of channel layers include a first channel layer as a lowermost channel layer, a second channel layer as a channel layer directly above the first channel layer, and
a lowermost portion of the third epitaxial layer is disposed on a level, lower than a level of a lower surface of the second channel layer.

20. A semiconductor device comprising:
an active region extending on a substrate in a first direction that is parallel to an upper surface of the substrate;
a plurality of channel layers on the active region and are spaced apart from each other in a vertical direction that is perpendicular to the upper surface of the substrate;
a gate structure intersecting the active region and the plurality of channel layers and extending on the substrate in a second direction that is parallel to the upper surface of the substrate, and surrounding each of the plurality of channel layers; and
a source/drain region that is adjacent to the gate structure on the active region and contacts the plurality of channel layers,
wherein the source/drain region comprises:
a first epitaxial layer including first layers on side surfaces of the plurality of channel layers, respectively, and a second layer at a low end of the source/drain region on the active region;
a second epitaxial layer, filling a space between the first layers and the second layer, and having a recessed upper surface;
a third epitaxial layer on the second epitaxial layer; and
a fourth epitaxial layer between the second epitaxial layer and the third epitaxial layer,
each of the first epitaxial layer, the second epitaxial layer, and the third epitaxial layer includes a silicon epitaxial layer,
the fourth epitaxial layer includes a silicon-germanium layer, and
the fourth epitaxial layer has a thickness in a range of about 1 angstrom (Å) to about 2 nanometers (nm).
